(19) United States
(12) Patent Application Publication
(10) Pub. No.: US 2026/0064929 A1
(43) Pub. Date: Mar. 5, 2026

(54) METHOD AND APPARATUS FOR ROUTING ON CHIP LAYOUT, DEVICE, AND STORAGE MEDIUM

(71) Applicant: Tencent Technology (Shenzhen) Company Limited, Shenzhen (CN)

(72) Inventors: Xiong XU, Shenzhen (CN); Kai Ye, Shenzhen (CN); Sainan HUAI, Shenzhen (CN); Shengyu ZHANG, Shenzhen (CN); Yicong ZHENG, Shenzhen (CN)

(21) Appl. No.: 18/783,258

(22) Filed: Jul. 24, 2024

Related U.S. Application Data
(63) Continuation of application No. PCT/CN2023/130560, filed on Nov. 8, 2023.

(30) Foreign Application Priority Data
Sep. 7, 2023 (CN) 202311160318.1

(51) Int. Cl. G06F 30/394

(52) U.S. Cl. CPC G06F 30/394

(57) ABSTRACT

This application discloses a method for designing routing on a chip layout performed by a computer device. The method includes: obtaining routing from a first routing port to a second routing port on the chip layout, the routing comprising tangent segments and circular arcs, each circular arc having a first endpoint and a second endpoint with the first endpoint being the same as an endpoint of a corresponding tangent segment connected to the circular arc; identifying, among the circular arcs comprised in the routing, a target circular arc in a winding-around state, in which a central angle corresponding to the target circular arc from its first endpoint to its second endpoint is greater than a threshold; and removing the target circular arc from the routing to obtain an updated routing that no winding-around state between a pair of adjacent tangent segment and circular arc.

### CROSS-REFERENCE TO RELATED APPLICATIONS

This application is a continuation application of PCT Patent Application No. PCT/CN2023/130560, entitled “METHOD AND APPARATUS FOR ROUTING ON CHIP LAYOUT, DEVICE, AND STORAGE MEDIUM” filed on Nov. 8, 2023, which claims priority to Chinese Patent Application No. 202311160318.1, entitled “METHOD AND APPARATUS FOR ROUTING ON CHIP LAYOUT, DEVICE, AND STORAGE MEDIUM” and filed on Sep. 7, 2023, both of which are incorporated herein by reference in their entirety.

### FIELD OF THE TECHNOLOGY

Embodiments of this application relate to the field of quantum technologies, and in particular, to a method and an apparatus for routing on a chip layout, a device, and a storage medium.

### BACKGROUND OF THE DISCLOSURE

In the field of quantum technologies, a chip layout generally needs to be designed to prepare a corresponding quantum chip. Arrangements of components, connection manners of components, and the like may be designed on the chip layout.

In the related art, when routing is performed for components to be connected on a chip layout, a component that needs to be bypassed is generally determined according to a source port and a destination port, and a circular arc line is arranged at the component that needs to be bypassed, to bypass the component.

However, in the related art, the circular arc line may be arranged winding around. To be specific, a central angle of the circular arc line arranged around a component that needs to be bypassed is excessively large, so that the circular arc line overlaps with another line, causing determined routing to be relatively inappropriate.

### SUMMARY

Embodiments of this application provide a method and an apparatus for routing on a chip layout, a device, and a storage medium, which can improve accuracy of routing. The technical solutions are as follows:

According to an aspect of the embodiments of this application, a method for designing routing on a chip layout is performed by a computer device, and the method includes:
obtaining routing from a first routing port to a second routing port on the chip layout, the routing comprising tangent segments and circular arcs, each circular arc having a first endpoint and a second endpoint with the first endpoint being the same as an endpoint of a corresponding tangent segment connected to the circular arc;
identifying, among the circular arcs comprised in the routing, a target circular arc in a winding-around state, in which a central angle corresponding to the target circular arc from its first endpoint to its second endpoint is greater than a threshold; and
removing the target circular arc from the routing to obtain an updated routing that no winding-around state between a pair of adjacent tangent segment and circular arc.

According to an aspect of the embodiments of this application, a chip is provided. The chip is obtained by manufacturing based on a chip layout. Routing of the chip layout is obtained by performing the method for routing on a chip layout.

According to an aspect of the embodiments of this application, a computer device is provided. The computer device includes a processor and a memory. The memory has a computer program stored therein that, when executed by the processor, causes the computer device to perform the computer program to implement the method for routing on a chip layout.

According to an aspect of the embodiments of this application, a non-transitory computer-readable storage medium is provided. The computer-readable storage medium has a computer program stored therein that, when executed by a processor of a computer device, causes the computer device to implement the method for routing on a chip layout.

The technical solutions provided in the embodiments of this application have the following beneficial effects:

Recognition is performed on circular arcs during routing. A circular arc with a central angle greater than a threshold is recognized, and the circular arc is deleted, so that adjusted routing does not include a circular arc with a central angle greater than the threshold. In other words, all circular arcs winding around are deleted, and circular arcs not winding around are reserved, to avoid overlapping of lines determined according to the routing due to winding around, so that the routing on the chip layout is more proper and accurate.

### BRIEF DESCRIPTION OF THE DRAWINGS

FIG. 1 is a schematic diagram of topological routing according to the related art.

FIG. 2 is a schematic diagram of routing according to the related art.

FIG. 3 is a schematic diagram of a winding-around state according to the related art.

FIG. 4 is a schematic diagram from topological routing to routing according to the related art.

FIG. 5 is a schematic diagram of another winding-around state according to the related art.

FIG. 6 is a schematic diagram of avoiding a winding-around state according to an embodiment of this application.

FIG. 7 is a flowchart of a method for routing on a chip layout according to an embodiment of this application.

FIG. 8 is a schematic diagram of a target circular arc according to an embodiment of this application.

FIG. 9 is a flowchart of a method for routing on a chip layout according to another embodiment of this application.

FIG. 10 is a schematic diagram of a target circular arc according to another embodiment of this application.

FIG. 11 is a flowchart of a method for routing on a chip layout according to another embodiment of this application.

FIG. 12 is a flowchart of a method for routing on a chip layout according to another embodiment of this application.

FIG. 13 is a flowchart of a method for routing on a chip layout according to another embodiment of this application.

FIG. 14 is a block diagram of a method for routing on a chip layout according to an embodiment of this application.

FIG. 15 is a schematic diagram of avoiding a winding-around state according to an embodiment of this application.

FIG. 16 is a block diagram of an apparatus for routing on a chip layout according to an embodiment of this application.

FIG. 17 is a block diagram of an apparatus for routing on a chip layout according to another embodiment of this application.

FIG. 18 is a structural block diagram of a computer device according to an embodiment of this application.

### DESCRIPTION OF EMBODIMENTS

To make objectives, technical solutions, and advantages of this application clearer, implementations of this application are further described below in detail with reference to the accompanying drawings.

Before embodiments of this application are introduced and described, some terms involved in this application are first explained and described.
1. Superconducting quantum chip: It is a central processing unit of a superconducting quantum computer. A quantum computer is a machine that performs calculation according to the principle of quantum mechanics. Based on the superposition principle of quantum mechanics and quantum entanglement, the quantum computer has a strong parallel processing capability, and can resolve some problems that are difficult to calculate by a classical computer. Zero-resistance characteristics of superconducting qubits and a manufacturing process close to that of integrated circuits enable a quantum computing system built by using the superconducting qubits to be one of the most promising systems for practical quantum computing.
2. Electronic design automation (EDA): It is a design manner in the electronic field. It means using computer software (aided design software) to complete design work in the electronic field and achieve automation of design, and includes, for example, function design, function verification, and layout and routing of integrated circuit chips. Software tools used herein are collectively referred to as EDA tools.
3. Automatic routing: It means automatic arrangement of lines in a circuit and chip design by using software, and connecting components according to rules and requirements. The automatic routing is mainly used as a link in large-scale and ultra-large-scale integrated circuit design, and is usually performed after arrangement of layout is completed.
4. Layout: It is also referred to as a circuit layout, and is a design drawing describing arrangement, placement, and connection of the components in the circuit. The layout is description of a physical situation of a real circuit in a form of planar geometric shapes. Design of the layout needs to conform to conditions of manufacturing processes, time sequences, areas, power consumption, and the like. A layout design document includes information about shapes, area, and positions of all hardware units on the chip.
5. Component: It is a collective term of elements and devices, and represents electronic components and constituent elements in circuits, such as resistors, capacitors, and inductors.
6. Co-planar waveguide (CPW): It is a microwave planar transmission line with superior performance and convenient processing, and is configured to transmit microwave signals. A co-planar waveguide technology is heavily used in the superconducting quantum chips.
7. Radius of curvature: It is a reciprocal of a curvature, and is represented by R. For a curve, the radius of curvature is equal to a radius of a circular arc closest to a curve of a point.
8. Microwave: It is an electromagnetic wave with a wavelength between infrared and a radio wave, and with a frequency ranging from 300 MHz to 300 GHz, which is higher than a radio frequency, and is also referred to as an ultra-high frequency electromagnetic wave. The microwave is used in a radar, a wireless network, and a sensor. In superconducting quantum, the microwave located in a resonant cavity can carry and store a quantum state, so that the microwave is used for quantum information processing.
9. Phase: It is a measure that describes a change in a signal waveform, and a unit is a degree (deg) or a radian (rad).
10. Topology: Topology is a discipline that studies topological spaces. It is developed from geometry and set theory. It mainly studies properties of geometric figures or spaces that remain unchanged after continuous changes in shape. Researches include space, dimension, transformation, and other concepts. The topology only considers a positional relationship between objects rather than a shape or a size. Topological routing is a routing manner based on a topological structure and a topological network.
11. Resonance: It is fully referred to as simple harmonic vibration, and is also referred to as resonance in physics. In electronics, when an input impedance and an output impedance of a circuit are almost 0 and a transfer function is close to 1, impedances or admittances of circuit elements cancel each other out, and the circuit oscillates at a specific frequency (a resonance frequency), causing the circuit to generate a higher current and a higher voltage than an input current and voltage. This phenomenon is referred to as electrical resonance or circuit resonance. In quantum mechanics, resonance of particles is similar to a situation in classical physics.

In the related art, a topological routing algorithm is another type of routing algorithm different from a grid routing algorithm. A process of the topological routing may be roughly decomposed into the following stages: (1) Mincut (a minimum cut algorithm) is performed on a line arrangement in which placement has been completed (components have been placed), to divide the arrangement into independent chip arrangements. (2) Multi-layer planning is performed on an individual chip, and cross-layer auxiliary components such as through holes are introduced, to divide the individual chip into independent layers of lines. Generally, positions of the components are fixed, and positions of components on different layers do not intersect. (3) Triangulation is performed on components on each layer of lines, and the topological algorithm is introduced to implement topological directions between a plurality of pairs of routing ports. The topological direction is a line pair connecting a source port to a destination port and bypassing an existing component. The routing port includes the source port and the destination port. The source port is a pin (a control/read pin of a bit), and the destination port is a pad (a pad around the chip). A routing process is to find a proper line to connect the pin to the pad. The routing port also belongs to components on the chip layout, equivalent to two types of special devices. The pin and the pad need to be determined first, and then the routing process is to find a line to connect the pin and the pad. In addition, the line does not intersect with another device, and a route is as short as possible. In other words, polygons abstracted from components on different layers are merged on a same layer (different components generally do not intersect with each other), and then Delaunay Triangulation (DT) is performed on all the polygons. After the Delaunay Triangulation, a large number of connection lines between points of the polygons corresponding to the components are obtained. (4) Corresponding final routing is generated for each group of topological routing. A requirement on the routing is to bypass the components. Therefore, a specific distance is obtained starting from an endpoint of the polygon along the connection lines obtained through the triangulation, and a path required for the routing can be determined. In some embodiments, the triangulation is implemented through a Constrained Delaunay Triangulation (CDT) algorithm based on the DT algorithm, that is, some limiting edges are added based on the DT. An objective of the DT algorithm is to segment a planar point set to form triangles, and a circumcircle of each triangle cannot include a fixed point of another triangle.

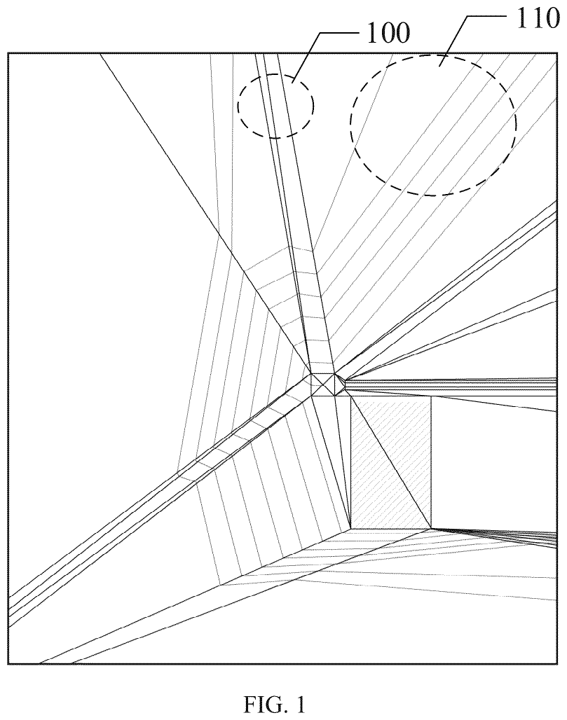

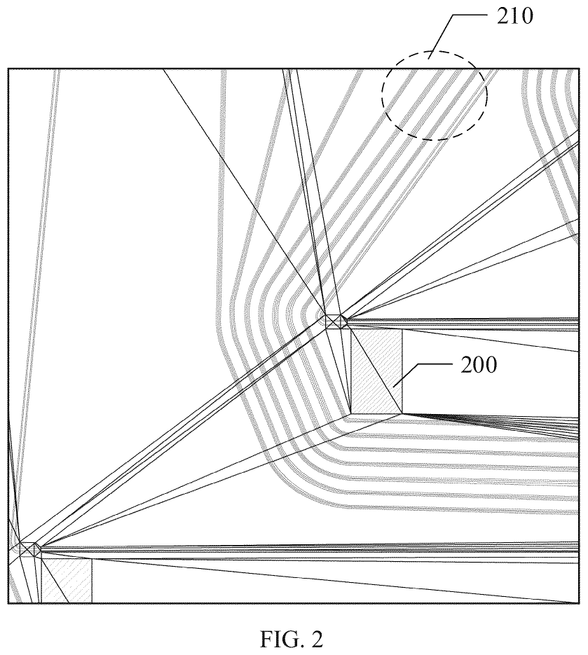

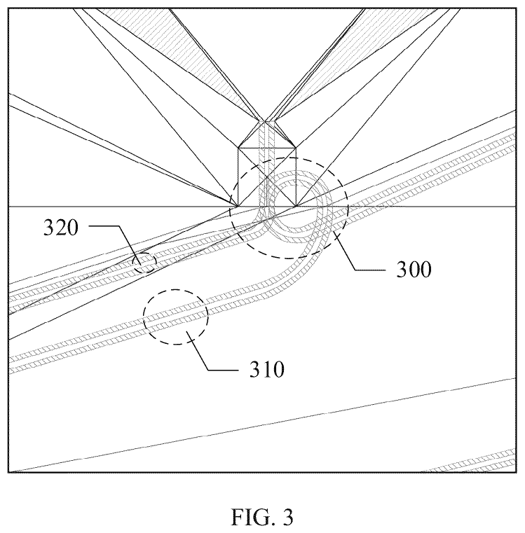

However, in the related art, when the topological routing is converted into the routing, due to some blind spots in the algorithm, a line in the converted routing may wind around a circle. FIG. 1 shows an algorithm output of the topological routing. A plurality of initial signal lines 110 formed by initial path points pass through a triangulated grid 100 formed by components. FIG. 2 shows normal routing. A plurality of lines 210 that are normally arranged do not intersect or overlap with each other. In some embodiments, a triangulation line and a square obstacle (a component that needs to be bypassed) that needs to be bypassed are determined according to components and routing ports on a chip layout, and a proper distance is selected from a fixed point of the obstacle along the triangulation line based on a spacing. The spacing herein is a shortest spacing specified in advance between different lines, and a shortest spacing between the lines and the components. FIG. 2 shows a plurality of topological paths that are finally implemented when a plurality of lines need to bypass a same obstacle, and different distances are respectively selected. An intersection point between the triangulation line and the initial signal line is a topological path point of different lines (a plurality of lines need to be arranged at the same time) found in this operation. FIG. 3 shows abnormal routing. Arranged lines 310 wind around a circle at a position 300, causing the arranged lines 310 and arranged lines 320 to intersect at the position 300.

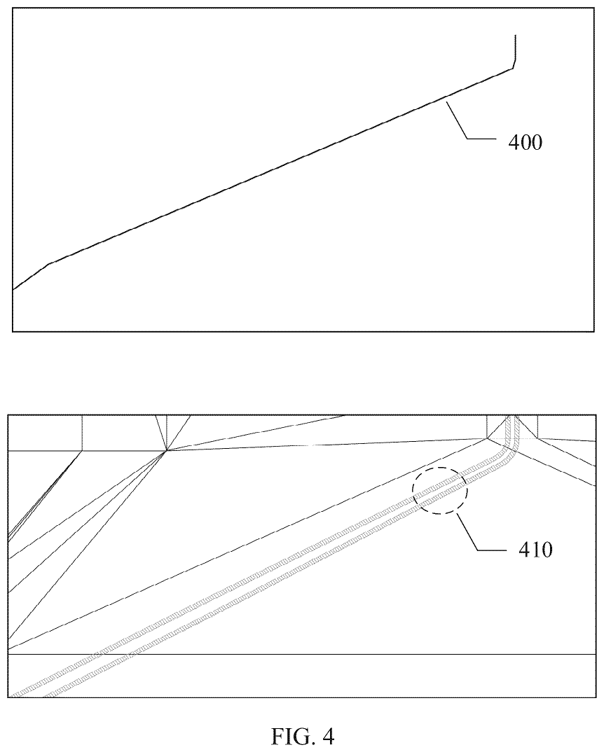

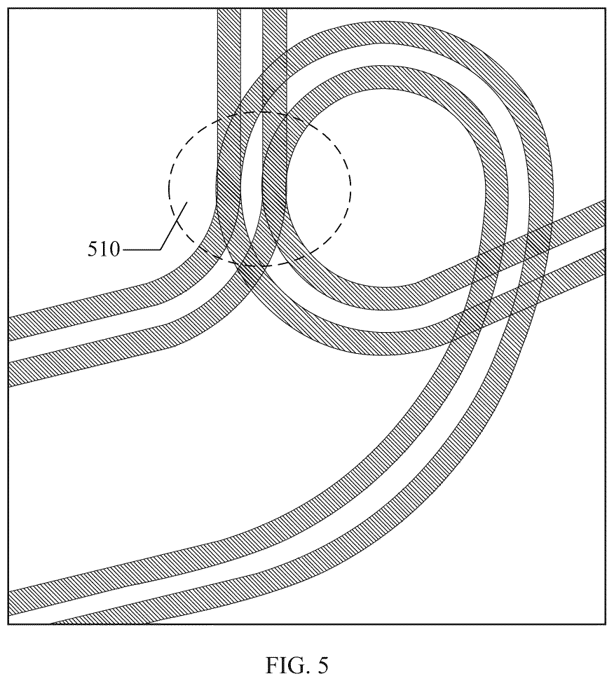

Specifically, in the routing algorithm in the related art, path points around each signal line that needs to be arranged are first determined. Then the path points are traversed to find proper path points. Triangulation endpoints (a triangulation endpoint is a vertex of a series of line segments obtained through triangulation performed on a plurality of all inputted polygons that are abstracted (from components) on the chip layout that need to be bypassed are determined according to specific situations of triangulation endpoints near the path points. That is, centers, radius, and start points and end points of a series of circular arcs in a final routing path are determined. Finally, the circular arcs are connected through tangents to form final signal lines. The triangulation endpoints are vertexes in the embodiments of this application. The triangulation endpoints and the vertexes have the same meaning, and both indicate vertexes of the polygons corresponding to the components. As shown in FIG. 4, topological routing 400 includes a plurality of path points obtained through the topological algorithm. In some embodiments, routing 410 is determined according to the topological routing 400. In some embodiments, the routing may wind around a circle. As shown in FIG. 5, one of two arranged CPW lines winds around a circle, and intersects with the other CPW line at a position 510. A consequence caused by winding around is apparent in both FIG. 3 and FIG. 5. A signal of the CPW is interrupted due to a routing error, and adjacent routing is interrupted due to winding-around routing. Therefore, this defect from the topological routing to the routing needs to be resolved.

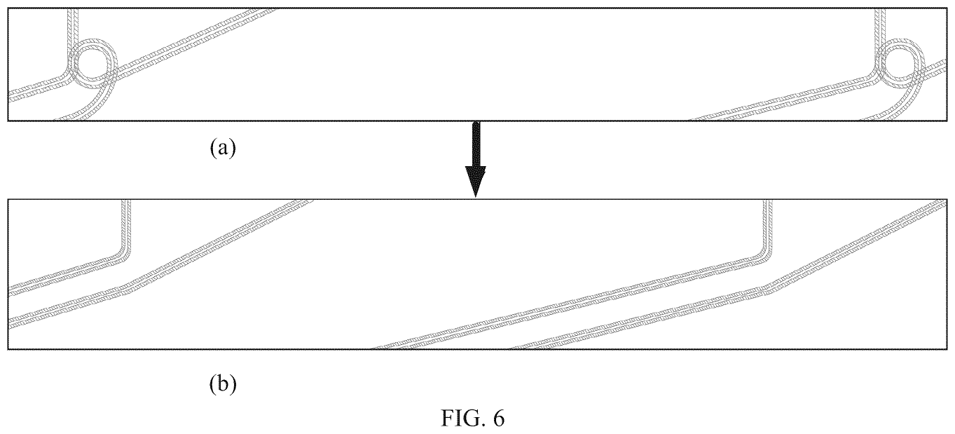

The solutions provided in the embodiments of this application provide a general supplementary algorithm for resolving such winding-around problem through in-depth analysis of a rendering algorithm from the topological routing to the routing. As shown in FIG. 6, (a) shows a situation in which lines intersect due to winding around, (b) shows lines normally arranged by avoiding the winding around. This application implements a process from (a) to (b). In this application, an algorithm that can automatically recognize and properly avoid a winding-around state of signal lines during routing is researched and developed based on the topological routing, to prevent the automatically arranged signal lines from intersecting and prevent a distance between the signal lines from being excessively short due to the foregoing reason, so that an automatic routing requirement of a superconducting quantum chip is satisfied. Therefore, this application has the following innovations: EDA automatic routing for superconducting quantum chips, automatic recognition of a winding-around state of signal lines, and intelligently selecting proper routing paths according to different winding-around states.

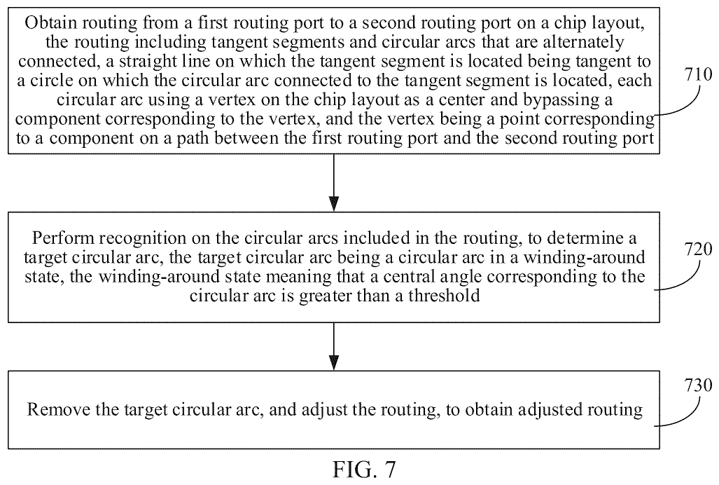

FIG. 7 is a flowchart of a method for routing on a chip layout according to an embodiment of this application. The method may be performed by a computer device. The computer device may be any electronic device having computing and storage capabilities, such as a personal computer (PC), a tablet computer, or a server. For example, the computer device may run a computer program configured to perform the method, and the method for routing on a chip layout provided in this embodiment is implemented through the computer program. As shown in FIG. 7, the method may include at least one of the following operations 710 to 730.

Operation 710. Obtain routing from a first routing port to a second routing port on a chip layout, the routing including tangent segments and circular arcs that are alternately connected, a straight line on which the tangent segment is located being tangent to a circle on which a circular arc connected to the tangent segment is located, each circular arc using a vertex on the chip layout as a center and bypassing a component corresponding to the vertex, and the vertex being a point corresponding to a component on a path between the first routing port and the second routing port.

A chip layout is a design drawing describing arrangement, placement, and connection of components in a circuit, and is description of a physical situation of a real circuit in a form of planar geometric shapes. The chip layout may be a chip layout of a quantum chip, for example, a chip layout of a superconducting quantum chip. The co-planar waveguide technology is greatly used in superconducting quantum chips for transmitting microwave signals. A layout design document of the chip layout includes information about shapes, area, positions, and the like of all hardware units on the chip. Through automatic routing, information about routing connecting point positions may be added in the layout design document, to finally generate a layout design document carrying routing information. The routing information may include position information of the components, or may further include position information of connection between the components.

In some embodiments, the first routing port and the second routing port are considered as a pair of routing ports. The first routing port may be considered as a start position of routing, and the second routing port may be considered as an end position of routing. Generally, in a chip layout including a plurality of components, a plurality of pairs of routing ports need to be included. A quantity of routing ports is not limited in this embodiment of this application, and a quantity of routing ports requiring routing is not limited in this embodiment of this application. An example in which routing is performed by using one pair of routing ports is only used as an example in this embodiment of this application, and routing of other pairs of routing ports refers to this embodiment of this application. After it is determined that all pairs of routing ports on the chip layout are completed, routing of the chip layout is considered to be completed. Certainly, the ports that need to be connected are set in advance by developers or determined in advance according to an algorithm. In this embodiment of this application, routing work is performed subsequently after the routing ports that need to be connected are determined.

The first routing port is a component or a part of the component. In some embodiments, the first routing port is a special component, and the component is a start of routing. In some other embodiments, the first routing port is a pin of a component. For example, the first routing port is a pin (a control/reading pin of a bit). In some embodiments, different components on the chip layout and different pins in the components have different features. Assuming that a component a and a component b need to be connected, the component a is first found, then a pin that meets a pin feature is found from pins of the component a, and the pin is used as the first routing port.

The second routing port is a component or a part of the component. In some embodiments, the second routing port is a special component, and the component is an end of routing. In some other embodiments, the second routing port is a pad of a component. For example, the second routing port is a pad (a pad around the chip). In some embodiments, a routing process is to find a proper line connecting the pin to the pad. Assuming that a component a and a component b need to be connected, after a pin that meets a pin feature is found from pins of the component a, a pad of the component b is found, and the pad is used as the second routing port.

In some embodiments, the first routing port and the second routing port may be separated by a plurality of components. Therefore, the components on an intermediate path need to be bypassed. As shown in FIG. 2, a rectangle 200 represents a component on the chip layout. Generally, during designing of the chip layout, the components are patterned. To be specific, the components correspond to various patterns on the chip layout. The rectangle 200 shown in FIG. 2 is a result of patterning components. Different components may correspond to different patterns, and different patterns may have different numbers of vertexes. During routing, which vertex of the rectangle 200 to bypass needs to be considered. In some embodiments, during routing, circular arc lines are arranged at the vertex that needs to be bypassed, to bypass the component. Therefore, when a plurality of components are passed by, a plurality of vertexes need to be bypassed, that is, there are a plurality of circular arcs. In some embodiments, the vertex is an endpoint, namely, a triangulation endpoint, of a triangulation line obtained through constrained Delaunay Triangulation performed on the components on the chip layout. For example, the point corresponding to the component, namely, the triangulation endpoint, is a vertex of a polygon corresponding to the component. The polygon corresponding to the component is that a polygon is used for representing a real component in an algorithm level, and the polygon represents a size and a shape of the component. The real components and the polygons on the chip layout are in one-to-one correspondence.

In some embodiments, the routing in operation 710 may be initial routing, or may be routing during adjustment, which is not limited in this application. The initial routing is routing that is first determined according to the first routing port and the second routing port and is not adjusted. In some embodiments, the initial routing includes at least one circular arc using the vertex as a center and at least two tangent segments connected to the circular arc. For example, when there is only one component that needs to be bypassed, the circular arc corresponding to the vertex of the component is determined. A connection line between a start position of the circular arc and the first routing port is tangent to the circular arc, and a connection line between an end position of the circular arc and the second routing port is tangent to the circular arc. Certainly, a quantity of components that need to be bypassed is not limited in the embodiments of this application. The quantity of components that need to be bypassed is positively correlated with a quantity of circular arcs in the routing, and when more components need to be bypassed, the quantity of the circular arc in the routing is correspondingly increased.

In addition, “alternately connected” in this embodiment of this application means that the circular arcs and the tangent segments are alternately connected. To be specific, one circular arc is connected to a preceding tangent segment and a following tangent segment, and one tangent segment is connected to at least one circular arc. When the tangent segment is a tangent segment passing by the first routing port, the tangent segment is only connected to one circular arc; and when the tangent segment is a tangent segment passing by the second routing port, the tangent segment is only connected to one circular arc. Each of other tangent segments than the two tangent segments connected to the first routing port or the second routing port is connected to a preceding circular arc and a subsequent circular arc.

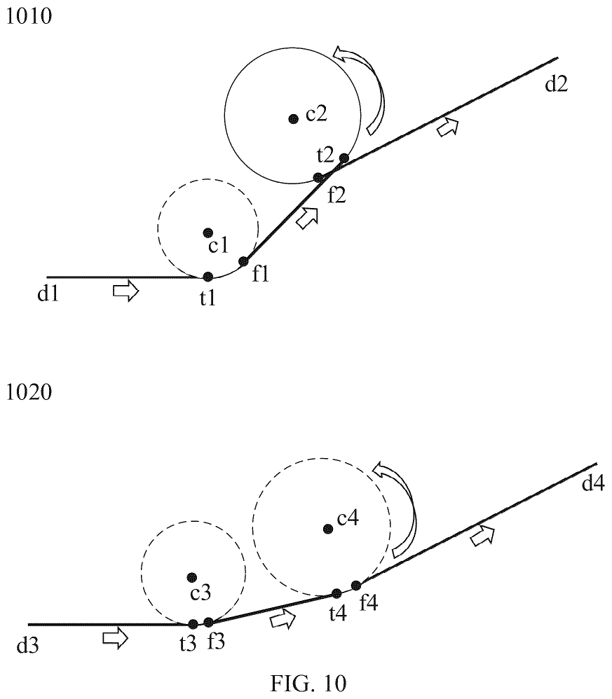

In some embodiments, a degree of a central angle of each circular arc and a length of each tangent segment are not limited, the circular arc is separately tangent to the preceding tangent segment and the following tangent segment. That is, the circular arcs and the tangent segments are alternately connected one-by-one in the routing. In some embodiments, the tangent segments and the circular arcs are alternately connected in the routing. In some embodiments, a start of the routing is the tangent segment connected to the first routing port, and an end of the routing is the tangent segment connected to the second routing port. In some embodiments, as shown in 1020 in FIG. 10, a line segment d3t3, a circular arc t3 counterclockwise to f3, a line segment f3t4, a circular arc t4 counterclockwise to f4, and a line segment f4d4 are connected in sequence, to obtain routing from the first routing port d3 to the second routing port d4, and the line segment d3t3, the line segment f3t4, and the line segment f4d4 are all tangent segments. That is, the tangent segments and the circular arcs are connected alternately. The line segment d3t3 is tangent to a circle in which the circular arc t3 counterclockwise to f3 is located and c3 is used as a center, the line segment f3t4 is tangent to both the circle in which the circular arc t3 counterclockwise to f3 is located and c3 is used as the center and a circle in which the circular arc t4 counterclockwise to f4 is located and c4 is used as a center, and the line segment f4d4 is tangent to the circle in which the circular arc t4 counterclockwise to f4 is located and c4 is used as the center. A start of the routing is the tangent segment d3t3 connected to the first routing port d3, and the end of the routing is the tangent segment f4d4 connected to the second routing port d4.

In some embodiments, two tangent circular arcs may be connected. In this case, a position at which the two circular arcs are connected is tangent to each of the two circular arcs. It is considered that there is a tangent segment at the position at which the two circular arcs are connected, and the tangent segment connects the two circular arcs, only a length of the tangent segment is limited.

Operation 720. Perform recognition on the circular arcs included in the routing, to determine a target circular arc, the target circular arc being a circular arc in a winding-around state, the winding-around state meaning that a central angle corresponding to the circular arc is greater than a threshold.

In some embodiments, winding-around recognition is performed on at least one circular arc included in the routing, to determine the target circular arc. The circular arc in the winding-around state is considered as a circular arc with a central angle greater than the threshold in this embodiment of this application. Because during routing in this embodiment of this application, each circular arc corresponds to a preceding tangent segment and a following tangent segment, when the central angle corresponding to the circular arc is excessively large, the preceding tangent segment intersects with the following tangent segment, causing the winding-around state. In some embodiments, the threshold is equal to 180 degrees. When the central angle corresponding to the circular arc is greater than 180 degrees, it is considered that the circular arc is in the winding-around state. Certainly, a specific value of the threshold is not limited in the embodiments of this application.

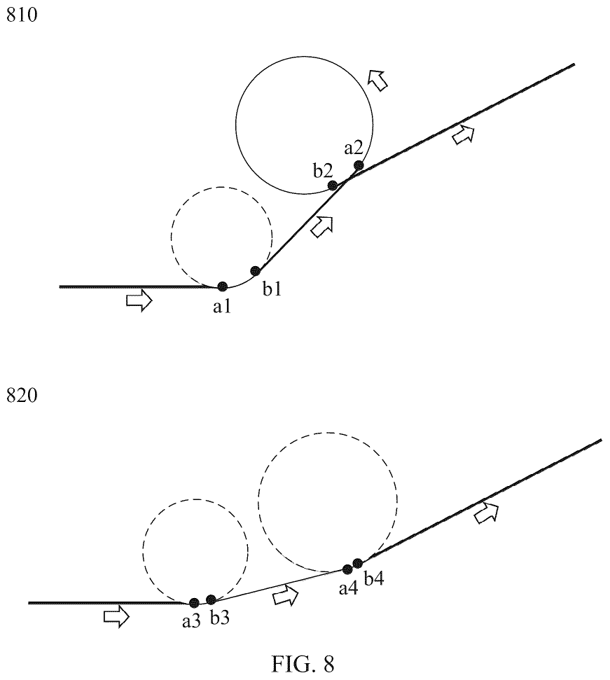

In some embodiments, as shown in FIGS. 8, 810 shows that there is a target circular arc. A central angle of a circular arc from a point a1 counterclockwise to a point b1 is less than the threshold, and the circular arc a1 counterclockwise to b1 does not belong to the target circular arc. A central angle of a circular arc from a point a2 counterclockwise to a point b2 is greater than the threshold, and the circular arc a2 counterclockwise to b2 belongs to the target circular arc. In some embodiments, as shown in FIGS. 8, 820 shows that there is no target circular arc. A central angle of a circular arc from a point a3 counterclockwise to a point b3 is less than the threshold, and the circular arc a3 counterclockwise to b3 does not belong to the target circular arc. A central angle of a circular arc from a point a4 counterclockwise to a point b4 is less than the threshold, and the circular arc a4 counterclockwise to b4 does not belong to the target circular arc. That is, in FIG. 8, the target circular arc determined according to operation 720 is only the circular arc a2 counterclockwise to b2.

In some embodiments, the recognition in operation 720 may also be referred to as winding-around recognition, circling recognition, or winding-around circling recognition.

Operation 730. Remove the target circular arc, and adjust the routing, to obtain adjusted routing.

In some embodiments, after determining the target circular arc, the target circular arc is removed, and the routing is re-determined. For example, the target circular arc and preceding tangent segment and the following segment corresponding to the target circular arc are all removed. Remaining lines are reconnected, and the foregoing routing requirements are satisfied, to obtain the adjusted routing.

In the technical solutions provided in this embodiment of this application, recognition is performed on the circular arcs in the routing, a circular arc with a central angle greater than the threshold are recognized, and the circular arc is deleted, so that the adjusted routing does not include the circular arc with the central angle greater than the threshold. That is, all the circular arcs in a winding-around state are deleted, and the circular arcs not in the winding-around state are reserved. Tangent segments connected to the reserved circular arcs are re-determined, to obtain renewed circular arcs. It is continuously determined whether the renewed circular arcs are in the winding-around state until all the circular arcs in the routing are not in the winding-around state, to obtain final routing. Therefore, overlapping of the lines determined according to the routing due to winding around is avoided, so that the routing on the chip layout is more proper and accurate.

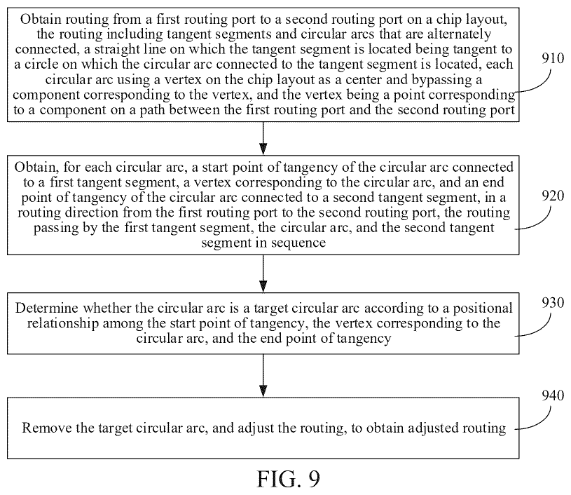

FIG. 9 is a flowchart of a method for routing on a chip layout according to another embodiment of this application. The method may be performed by a computer device. The computer device may be any electronic device having computing and storage capabilities, such as a PC, a tablet computer, or a server. For example, the computer device may run a computer program configured to perform the method, and the method for routing on a chip layout provided in this embodiment is implemented through the computer program. As shown in FIG. 9, the method may include at least one of the following operations 910 to 940.

Operation 910. Obtain routing from a first routing port to a second routing port on the chip layout, the routing including tangent segments and circular arcs that are alternately connected, a straight line on which the tangent segment is located being tangent to a circle on which a circular arc connected to the tangent segment is located, each circular arc using a vertex on the chip layout as a center and bypassing a component corresponding to the vertex, and the vertex being a point corresponding to a component on a path between the first routing port and the second routing port.

Operation 920. Obtain, for each circular arc, a start point of tangency of the circular arc connected to a first tangent segment, a vertex corresponding to the circular arc, and an end point of tangency of the circular arc connected to a second tangent segment, in a routing direction from the first routing port to the second routing port, the routing passing by the first tangent segment, the circular arc, and the second tangent segment in sequence.

In some embodiments, preceding and following tangent segments are considered to include a preceding tangent segment (the first tangent segment) and a following tangent segment (the second tangent segment). A point of tangency between the first tangent segment and the circular arc is considered as the start point of tangency of the circular arc, and a point of tangency between the second tangent segment and the circular arc is considered as the end point of tangency of the circular arc. In the routing direction from the first routing port to the second routing port, the start point of tangency is first passed by, then the circular arc is passed by, and the end point of tangency is finally passed by.

In some embodiments, as shown in 1010 in FIG. 10, in the routing direction from the first routing port to the second routing port, a start point of tangency t1 of the first circular arc using c1 as a center is first passed by, and then a circular arc t1 counterclockwise to f1 is passed by. f1 is an end point of tangency of the circular arc. After the first circular arc is passed by, a line segment f1t2 is passed by. t2 is considered as a start point of tangency of the second circular arc using c2 as a center. A circular arc t2 counterclockwise to f2 is passed by, and the routing is continued in a direction of a tangent at an end point of tangency f2. A line segment d1t1 is a first tangent segment of the circular arc using c1 as the center, and the line segment f1t2 is a second tangent segment of the circular arc using c1 as the center. Moreover, the line segment f1t2 is a first tangent segment of the circular arc using c2 as the center, and a line segment f2d2 is a second tangent segment of the circular arc using c2 as the center.

Operation 930. Determine whether the circular arc is the target circular arc according to a positional relationship among the start point of tangency, the vertex corresponding to the circular arc, and the end point of tangency.

In some embodiments, when a routing direction on the circular arc is counterclockwise, when a direction from the start point of tangency, the vertex corresponding to the circular arc, to the end point of tangency is counterclockwise, it is determined that the circular arc is the target circular arc. In some embodiments, when the direction from the start point of tangency, the vertex corresponding to the circular arc, to the end point of tangency is clockwise, it is determined that the circular arc is not the target circular arc. On the contrary, when the routing direction on the circular arc is clockwise, when a direction from the start point of tangency, the vertex corresponding to the circular arc, to the end point of tangency is clockwise, it is determined that the circular arc is the target circular arc. In some embodiments, when the direction from the start point of tangency, the vertex corresponding to the circular arc, to the end point of tangency is counterclockwise, it is determined that the circular arc is not the target circular arc.

The routing direction of the circular arc in FIG. 10 is counterclockwise. In some embodiments, as shown in 1010 in FIG. 10, whether the circular arc using c1 as the center is the target circular arc is determined according to a positional relationship among the start point t1 of tangency, the vertex c1 corresponding to the circular arc, and the end point f1 of tangency. Because the direction from the start point t1 of tangency, the vertex c1 corresponding to the circular arc, to the end point f1 of tangency is clockwise, the circular arc is not the target circular arc. In some embodiments, whether the circular arc using c2 as the center is the target circular arc is determined according to a positional relationship among the start point t2 of tangency, the vertex c2 corresponding to the circular arc, and the end point f2 of tangency. Because the direction from the start point t2 of tangency, the vertex c2 corresponding to the circular arc, to the end point f2 of tangency is counterclockwise, the circular arc is the target circular arc.

In some embodiments, as shown in 1020 in FIG. 10, whether a circular arc using c3 as a center is the target circular arc is determined according to a positional relationship among a start point t3 of tangency, a vertex c3 corresponding to the circular arc, and an end point f3 of tangency. Because a direction from the start point t3 of tangency, the vertex c3 corresponding to the circular arc, to the end point f3 of tangency is clockwise, the circular arc is not the target circular arc. In some embodiments, whether a circular arc using c4 as a center is the target circular arc is determined according to a positional relationship among a start point t4 of tangency, a vertex c4 corresponding to the circular arc, and an end point f4 of tangency. Because a direction from the start point t4 of tangency, the vertex c4 corresponding to the circular arc, to the end point f4 of tangency is clockwise, the circular arc is not the target circular arc.

In some embodiments, operation 930 includes at least one of operations 931 to 933 (not shown in the figure).

Operation 931. Determine a first direction and a second direction, the first direction being a rotation direction from the start point of tangency to the end point of tangency to the vertex corresponding to the circular arc, and the second direction being a rotation direction from the start point of tangency along the circular arc to the end point of tangency, each of the rotation directions being clockwise or counterclockwise.

The first direction shown in operation 931 is the rotation direction from the start point of tangency to the end point of tangency to the vertex corresponding to the circular arc. Certainly, the first direction may be the rotation direction from the start point of tangency to the end point of tangency to the vertex corresponding to the circular arc, or may be a rotation direction from the end point of tangency to the vertex corresponding to the circular arc to the start point of tangency, or may be a rotation direction from the vertex corresponding to the circular arc to the start point of tangency to the end point of tangency. A specific form of the first direction is not limited in this application. Certainly, in addition to the first direction, other directions may alternatively be used to determine whether the circular arc is the target circular arc. For example, in the foregoing embodiment, in description of FIG. 10, a direction used for determining is the rotation direction from the start point of tangency to the vertex corresponding to the circular arc to the end point of tangency.

The second direction shown in operation 931 may be considered as the routing direction of the circular arc.

Operation 932. Determine, if the first direction is different from the second direction, that the circular arc is the target circular arc.

Operation 933. Determine, if the first direction is the same as the second direction, that the circular arc is not the target circular arc.

When the first direction shown in operation 931 is the rotation direction from the start point of tangency to the end point of tangency to the vertex corresponding to the circular arc, if the first direction is different from the second direction, it is determined that the circular arc is the target circular arc. If the first direction is the same as the second direction, it is determined that the circular arc is not the target circular arc.

Recognition is performed on the circular arcs in FIG. 10 by using the method in operations 931 to 933. As shown in FIG. 10, the second direction, to be specific, the routing direction of the circular arc, is counterclockwise. In some embodiments, as shown in 1010 in FIG. 10, for the circular arc using c1 as the center, the first direction, to be specific, the rotation direction from the start point t1 of tangency to the end point f1 of tangency to the vertex c1 corresponding to the circular arc, is counterclockwise, and the first direction is the same as the second direction, so that it is determined that the circular arc is not the target circular arc. For the circular arc using c2 as the center, the first direction, to be specific, the rotation direction from the start point t2 of tangency to the end point f2 of tangency to the vertex c2 corresponding to the circular arc, is clockwise, and the first direction is different from the second direction, so that it is determined that the circular arc is the target circular arc. In some embodiments, as shown in 1020 in FIG. 10, for the circular arc using c3 as the center, the first direction, to be specific, the rotation direction from the start point t3 of tangency to the end point f3 of tangency to the vertex c3 corresponding to the circular arc, is counterclockwise, and the first direction is the same as the second direction, so that it is determined that the circular arc is not the target circular arc. For the circular arc using c4 as the center, the first direction, to be specific, the rotation direction from the start point t4 of tangency to the end point f4 of tangency to the vertex c4 corresponding to the circular arc, is counterclockwise, and the first direction is the same as the second direction, so that it is determined that the circular arc is not the target circular arc.

Through the foregoing method, whether the circular arc is the target circular arc is determined depending on whether the first direction is consistent with the second direction, the solution is simple and convenient, and accuracy of the determined target circular arc is high.

In some embodiments, operation 930 further includes at least one of operations 934 to 936 (not shown in the figure).

Operation 934. Determine a central angle corresponding to the circular arc, the central angle using the vertex corresponding to the circular arc as a vertex, one edge of the central angle passing by the start point of tangency, and the other edge of the central angle passing by the end point of tangency.

A specific method for determining the central angle is not limited in this application. When positions of a center of a circle, a start point of tangency, and an end point of tangency are known, a degree of the central angle can be calculated according to an arc length formula l=πrα/180, where l is an arc length, r is a radius of the circular arc, and α is a degree of the central angle.

Operation 935. Determine, if the central angle is greater than a threshold, that the circular arc is the target circular arc.

Operation 936. Determine, if the central angle is less than or equal to the threshold, that the circular arc is not the target circular arc.

In some embodiments, if the central angle is greater than the threshold, it is determined that the circular arc is the target circular arc; or if the central angle is less than or equal to the threshold, it is determined that the circular arc is not the target circular arc. In some embodiments, the threshold is 180 degrees.

Operation 940. Remove the target circular arc, and adjust the routing, to obtain adjusted routing.

Through the foregoing method, whether the circular arc is the target circular arc is determined according to the degree of the central angle, a plurality of method for determining the target circular arc are provided, and diversity of manners of determining the target circular arc is improved.

In the technical solution provided in this embodiment of this application, whether the circular arc is the target circular arc is determined according to the positional relationship among the start point of tangency, the vertex corresponding to the circular arc, and the end point of tangency, so that the accuracy of the determined target circular arc can be high. In addition, two manners are specifically shown. One manner is determining whether the circular arc is the target circular arc depending on whether the first direction is consistent with the second direction, and the other manner is determining whether the circular arc is the target circular arc according to the degree of the central angle. Therefore, the diversity of the manners of determining the target circular arc is improved.

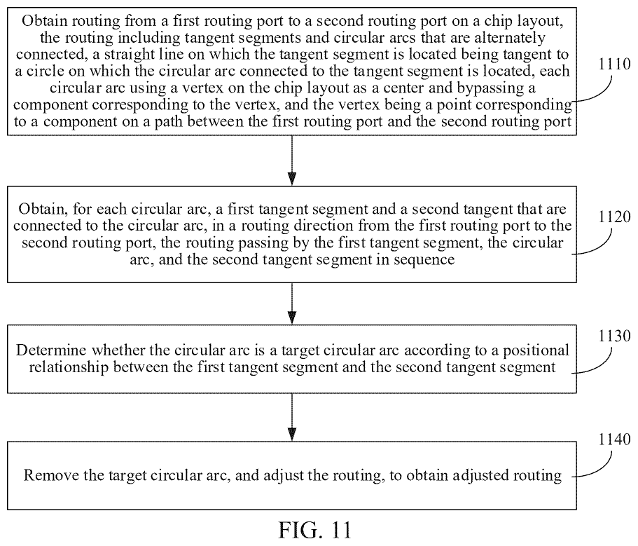

FIG. 11 is a flowchart of a method for routing on a chip layout according to another embodiment of this application. The method may be performed by a computer device. The computer device may be any electronic device having computing and storage capabilities, such as a PC, a tablet computer, or a server. For example, the computer device may run a computer program configured to perform the method, and the method for routing on a chip layout provided in this embodiment is implemented through the computer program. As shown in FIG. 11, the method may include at least one of the following operations 1110 to 1140.

Operation 1110. Obtain routing from a first routing port to a second routing port on the chip layout, the routing including tangent segments and circular arcs that are alternately connected, a straight line on which the tangent segment is located being tangent to a circle on which a circular arc connected to the tangent segment is located, each circular arc using a vertex on the chip layout as a center and bypassing a component corresponding to the vertex, and the vertex being a point corresponding to a component on a path between the first routing port and the second routing port.

Operation 1120. Obtain, for each circular arc, a first tangent segment and a second tangent that are connected to the circular arc, in a routing direction from the first routing port to the second routing port, the routing passing by the first tangent segment, the circular arc, and the second tangent segment in sequence.

In some embodiments, as shown in FIG. 10, a line segment d1t1 is a first tangent segment of a circular arc using c1 as a center, and a line segment f1t2 is a second tangent segment of the circular arc using c2 as the center. Moreover, the line segment f1t2 is a first tangent segment of a circular arc using c2 as a center, and a line segment f2d2 is a second tangent segment of the circular arc using c2 as the center.

Operation 1130. Determine whether the circular arc is the target circular arc according to a positional relationship between the first tangent segment and the second tangent segment.

In some embodiments, the positional relationship between the first tangent segment and the second tangent segment may include intersecting and not intersecting. In some embodiments, if the first tangent segment intersects with the second tangent segment, it may be considered that the circular arc connected to the first tangent segment and the second tangent segment winds around. In this case, it can be determined that the circular arc is the target circular arc.

In some embodiments, if the first tangent segment intersects with the second tangent segment, it is determined that the circular arc is the target circular arc. If the first tangent segment does not intersect with the second tangent segment, it is determined that the circular arc is not the target circular arc.

In some embodiments, as shown in 1010 in FIG. 10, the first tangent segment of the circular arc using c1 as the center does not intersect with the second tangent segment, and it is determined that the circular arc is not the target circular arc. The first tangent segment of the circular arc using c2 as the center does not intersect with the second tangent segment, it is determined that the circular arc is the target circular arc.

In some embodiments, as shown in 1020 in FIG. 10, the first tangent segment of the circular arc using c3 as the center does not intersect with the second tangent segment, and it is determined that the circular arc is not the target circular arc. The first tangent segment of the circular arc using c4 as the center does not intersect with the second tangent segment, it is determined that the circular arc is not the target circular arc

In some embodiments, it may be alternatively determined whether the circular arc is the target circular arc according to a position of an intersection point between the first tangent segment and the second tangent segment. For example, if there is no intersection point between the first tangent segment and the second tangent segment, or the intersection point between the first tangent segment and the second tangent segment is located on an extension line of the first tangent segment, or the intersection point between the first tangent segment and the second tangent segment is located on an extension line of the second tangent segment, it is considered that the circular arc does not in the winds around. Therefore, the circular arc is not the target circular arc, and does not need to be removed. If the intersection point between the first tangent segment and the second tangent segment is located on the first tangent segment and the second tangent segment, it is considered that the circular arc winds around, and needs to be removed. In this case, it is determined that the circular arc is the target circular arc.

Operation 1140. Remove the target circular arc, and adjust the routing, to obtain adjusted routing.

Other operations in this embodiment of this application refer to description of the foregoing embodiment, and are not described in detail herein.

In the technical solution provided in this embodiment of this application, whether the circular arc winds around and needs to be removed is determined depending on whether a preceding tangent segment and a following tangent segment of the circular arc intersect with each other. If the two tangent segments intersect with each other, it is considered that the circular arc winds around, and the circular arc needs to be removed. If the two tangent segments do not intersect with each other, it is considered that the circular arc does not wind around, and the circular arc does not need to be removed. Therefore, in this application, efficiency of recognition of the circular arc is improved by determining whether the tangent segments intersect with each other, and a routing speed is further improved.

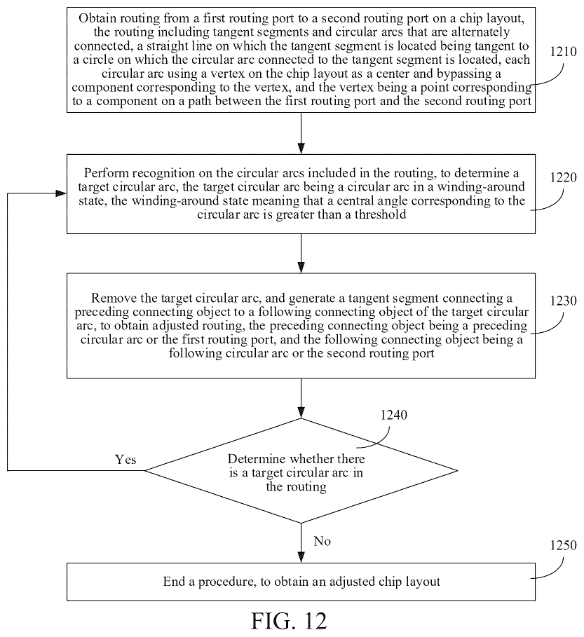

FIG. 12 is a flowchart of a method for routing on a chip layout according to another embodiment of this application. The method may be performed by a computer device. The computer device may be any electronic device having computing and storage capabilities, such as a PC, a tablet computer, or a server. For example, the computer device may run a computer program configured to perform the method, and the method for routing on a chip layout provided in this embodiment is implemented through the computer program. As shown in FIG. 12, the method may include at least one of the following operations 1210 to 1250.

Operation 1210. Obtain routing from a first routing port to a second routing port on the chip layout, the routing including tangent segments and circular arcs that are alternately connected, a straight line on which the tangent segment is located being tangent to a circle on which a circular arc connected to the tangent segment is located, each circular arc using a vertex on the chip layout as a center and bypassing a component corresponding to the vertex, and the vertex being a point corresponding to a component on a path between the first routing port and the second routing port.

Operation 1220. Perform recognition on the circular arcs included in the routing, to determine a target circular arc, the target circular arc being a circular arc in a winding-around state, the winding-around state meaning that a central angle corresponding to the circular arc is greater than a threshold.

Operation 1230. Remove the target circular arc, and generate a tangent segment connecting a preceding connecting object to a subsequent connecting object of the target circular arc, to obtain the adjusted routing, the preceding connecting object being a preceding circular arc or the first routing port, and the subsequent connecting object being a subsequent circular arc or the second routing port.

In some embodiments, when the target circular arc is removed, tangent segments connected to the target circular arc are also removed. For example, as shown in 1010 in FIG. 10, a first tangent segment of a circular arc using c2 as a center intersects with a second tangent segment, and it is determined that the circular arc is the target circular arc. When the target circular arc using c2 as the center is removed, a tangent segment f1 to t2 and a tangent segment f2 to d2 are also removed.

In some embodiments, after the target circular arc is removed, routing needs to be re-performed. In other words, the tangent segment connecting the preceding connecting object and the subsequent connecting object of the target circular arc needs to be generated, to obtain the adjusted routing. In some embodiments, the preceding connecting object of the target circular arc is the first routing port, and the subsequent connecting object is the subsequent circular arc. Therefore, a tangent segment connecting the first routing port and the subsequent circular arc needs to be generated. When a connecting manner changes, a central angle corresponding to the subsequent circular arc also changes. In some embodiments, the preceding connecting object of the target circular arc is the preceding circular arc, and the subsequent connecting object is the subsequent circular arc. Therefore, a common tangent connecting the preceding circular arc to the subsequent circular arc needs to be generated. When a connecting manner changes, central angles respectively corresponding to the preceding circular arc and the subsequent circular arc also change. In some embodiments, the preceding connecting object of the target circular arc is the preceding circular arc, and the subsequent connecting object is the second routing port. Therefore, a tangent segment connecting the preceding circular arc to the second routing port needs to be generated. When a connecting manner changes, a central angle corresponding to the preceding circular arc also changes.

In some embodiments, after the target circular arc is removed, a circular arc connecting the tangent segments that are connected to the target circular arc may alternatively be generated. As shown in 1010 in FIG. 10, the first tangent segment of the circular arc using c2 as the center intersects with a second tangent segment, and it is determined that the circular arc is the target circular arc. After the target circular arc using c2 as the center is removed, a circular arc connecting the tangent segment f1 to t2 to the tangent segment f2 to d2 is generated. However, a generated circular arc may be the same as the target circular arc using c2 as the center, causing repetition between processes of removing and generating the circular arc. Therefore, the method is not described in detail in this embodiment of this application.

Operation 1240. Determine whether there is a target circular arc in the routing.

In some embodiments, whether there is a target circular arc is continuously determined one-by-one for all circular arcs in the adjusted routing. In some other embodiments, recognition does not need to be performed on all the circular arcs, and the recognition is only re-performed on preceding and subsequent circular arcs of the deleted circular arc in the last adjustment. Because points of tangency respectively corresponding to the preceding and subsequent circular arcs are changed in the adjusted routing, a winding-around state of the preceding and subsequent circular arcs may change. However, other circular arcs than the preceding and subsequent circular arcs of the target circular arc are not affected. Therefore, the recognition only needs to be performed on the preceding and subsequent circular arcs after re-routing, and does not need to be performed on all the circular arcs, thereby improving recognition efficiency.

If there is a target circular arc, operation 1220 is performed. If there is no target circular arc, operation 1250 is performed.

Operation 1250. End a procedure, to obtain an adjusted chip layout.

In some embodiments, when no circular arc that needs to be removed is found through traversing the adjusted routing after the circular arc is removed, it is considered that there is no winding-around state in the routing, and it is considered that the routing is finally planned routing. That is, when routing is performed on a physical device according to the routing on the chip layout, lines in the physical device do not wind around. The routing in this embodiment of this application is at a chip layout level, and does not mean actually arranged signal lines, but reflects a real connection situation of the device in an electronic form.

In some embodiments, all the circular arcs are only traversed once, when it is determined that a circular arc is not the target circular arc, the recognition is performed on a subsequent circular arc. When it is determined that a circular arc is the target circular arc, the circular arc is removed, and preceding and subsequent connecting objects are re-connected. It is determined whether neither of the preceding and subsequent connecting objects after reconnection is an object that needs to be removed, and if neither needs to be removed, the recognition is continuously performed on a subsequent circular arc.

In the technical solution provided in this embodiment of this application, after the target circular arc winding around is removed, the tangent segment connecting the preceding connecting object to the subsequent connecting object of the target circular arc is generated, so that completeness of the routing can be ensured. Generating the tangent segment connecting the preceding connecting object to the subsequent connecting object of the target circular arc, instead of generating the circular arc connecting the tangent segments that are connected to the target circular arc, can avoid an error in the procedure caused by the winding-around state that also occurs in a process of adjustment of the routing.

In addition, the recognition is re-performed on the adjusted routing, ensuring that there is no circular arc winding around in the adjusted routing. Therefore, overlapping of the lines determined according to the routing due to winding around is avoided, so that the routing on the chip layout is more proper and accurate.

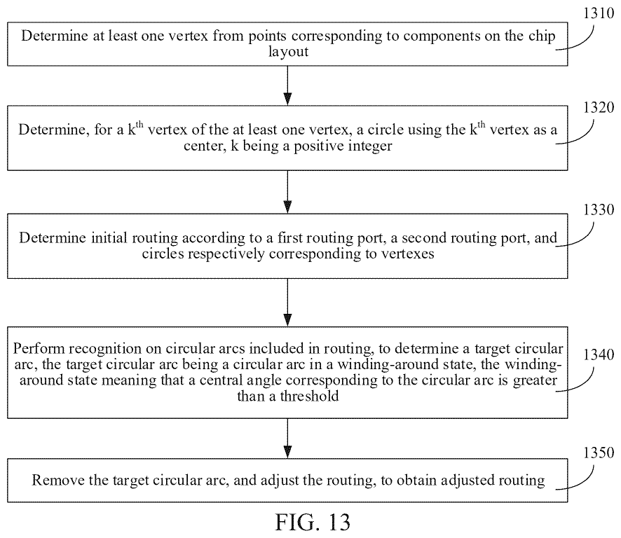

FIG. 13 is a flowchart of a method for routing on a chip layout according to another embodiment of this application. The method may be performed by a computer device. The computer device may be any electronic device having computing and storage capabilities, such as a PC, a tablet computer, or a server. For example, the computer device may run a computer program configured to perform the method, and the method for routing on a chip layout provided in this embodiment is implemented through the computer program. As shown in FIG. 13, the method may include at least one of the following operations 1310 to 1350.

Operation 1310. Determine at least one vertex from points corresponding to components on the chip layout.

In some embodiments, a vertex corresponding to an initial line segment is determined according to distances respectively from vertexes corresponding to the components to the initial line segment. The initial line segment is a line segment formed by a connection line between a first routing port and a second routing port. The vertex is used as a middle point, a first line segment is determined according to a connection line between the middle point and a start point of the initial line segment, and a second line segment is determined according to a connection line between the middle point and an end point of the initial line segment. The first line segment and the second line segment are used as the initial line segment separately, the operation of determining the vertex corresponding to the initial line segment is performed until a line segment formed by any two adjacent points corresponding to no vertex, and a procedure ends. Any one of adjacent points includes at least one of the following: the first routing port, at least one vertex that is determined, or the second routing port.

In some embodiments, positions of the components in the chip layout are fixed. In other words, positions of the points corresponding to the components are fixed. For the connection line between the first routing port and the second routing port, a vertex has a shortest distance from the connection line is determined, to be used as a vertex that needs to be bypassed determined based on the line segment. According to the vertex, the connection line between the first routing port and the second routing port is divided into two line segments. Whether there is a vertex that needs to be bypassed again for the two line segments respectively is determined. Until there is no vertex that needs to be bypassed in the line segment after bisection, search for the vertex that needs to be bypassed is stopped. In some embodiments, in addition to belonging to a minimum value, the determined distance from the vertex to the line segment further needs to satisfy at least a distance condition. For example, the distance from the vertex to the line segment further needs to be less than a first value. Only when the distance from the vertex to the line segment is the minimum value and less than the first value, it is determined that the vertex is the vertex that needs to be bypassed corresponding to the line segment.

Operation 1320. Determine, for a k^{th} vertex of the at least one vertex, a circle using the k^{th} vertex as a center, k being a positive integer.

In some embodiments, when the routing is determined, each vertex needs to be circled. A radius of a circle corresponding to each vertex is not limited in this application. The radius may be preset, or may be generated according to an algorithm.

In some embodiments, a radius of the circle corresponding to the k^{th} vertex is determined according to a quantity of lines that are arranged at the k^{th} vertex. When the quantity of lines that are arranged is 0, the radius of the circle corresponding to the k^{th} vertex is equal to a shortest safety distance. When the quantity of lines that are arranged is s, the radius of the circle corresponding to the k^{th} vertex is equal to a sum of the shortest safety distance and a product of s and a routing spacing, s being a positive integer, and the shortest safety distance and the routing spacing being constants. The circle using the k^{th} vertex as the center is determined according to the radius of the circle corresponding to the k^{th} vertex.

In some embodiments, the lines that are arranged at the k^{th} vertex herein may be considered as geometric lines planned to bypass the k^{th} vertex. For a point a, all geometric lines that are planned to be arranged bypassing the point a need to bypass the point a. As a quantity of planned lines increases, a radius of a circular arc bypassing the point a is greater.

In some embodiments, when the quantity of lines that are arranged is 0, the radius of the circle corresponding to the k^{th} vertex is equal to the shortest safety distance. When the quantity of lines that are arranged is s, radius r of circle corresponding to (s+1)^{th} line arrangement corresponding to k^{th} vertex=s*routing spacing+shortest safety distance. Specific values of the shortest safety distance and the routing are not limited in this application.

Operation 1330. Determine initial routing according to the first routing port, the second routing port, and circles respectively corresponding to the at least one vertex.

A specific manner of determining the initial routing according to the first routing port, the second routing port, and the circles respectively corresponding to the at least one vertex is not limited in this embodiment of this application, as long as determined routing satisfies a constraint condition. In some embodiments, the constraint condition for the routing is that the routing includes at least two tangent segments and at least one circular arc. The circular arc is respectively tangent to preceding and following tangent segments thereof. In some embodiments, the routing includes only the tangent segment and the circular arc.

In some embodiments, a tangent to a circle corresponding to the first vertex is determined through the first routing port, and a point of tangency is determined as a start point of tangency corresponding to the first vertex. A common tangent between the circle corresponding to the k^{th} vertex and a circle corresponding to a (k+1)^{th} vertex is made, an intersection point between the common tangent and the circle corresponding to the k^{th} vertex is determined as an end point of tangency corresponding to the k^{th} vertex, and an intersection point between the common tangent and the circle corresponding to the (k+1)^{th} vertex is determined as a start point of tangency corresponding to the (k+1)^{th} vertex. Through the second routing port, a tangent to a circle corresponding to a last vertex is determined, and a point of tangency is determined as an end point of tangency corresponding to the last vertex. A circular arc formed by the start point of tangency and the end of tangency corresponding to the k^{th} vertex is determined as the circular arc corresponding to the k^{th} vertex. Tangent segments and circular arcs corresponding to the at least one vertex are alternately connected in sequence starting from the first routing port until the second routing port is connected, to obtain the initial routing.

In some embodiments, when the common tangent between the circle corresponding to the k^{th} vertex and the circle corresponding to the (k+1)^{th} vertex is made, a tangent segment formed by two points of tangency does not intersect with a connection line segment between the k^{th} vertex and the (k+1)^{th} vertex.

Operation 1340. Perform recognition on the circular arcs included in the routing, to determine a target circular arc, the target circular arc being a circular arc in a winding-around state, the winding-around state meaning that a central angle corresponding to the circular arc is greater than a threshold.

Operation 1350. Remove the target circular arc, and adjust the routing, to obtain adjusted routing.

In the technical solution provided in this embodiment of this application, when the routing is determined, a proper vertex is selected as a vertex from vertexes of a component in a distance-first manner, and proper vertexes are determined through bisection for multiple times. A manner of determining vertexes through bisection can effectively improve accuracy of determined vertexes, and can greatly improve efficiency of determining vertexes.

Moreover, the routing determined by connecting the circular arcs and the tangent segments in sequence needs relatively the shortest signal lines, which is conducive to reducing routing costs. In addition, the radius of the circular arc is determined according to the quantity of lines that are arranged, which is conducive to avoiding intersection between lines, thereby improving accuracy of the routing.

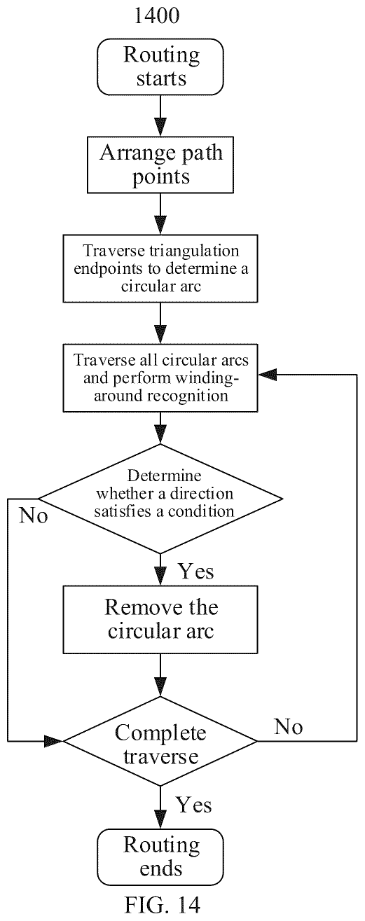

FIG. 14 is a block diagram of a method for routing on a chip layout according to an embodiment of this application. The method may be performed by a computer device. The computer device may be any electronic device having computing and storage capabilities, such as a PC, a tablet computer, or a server. For example, the computer device may run a computer program configured to perform the method, and the method for routing on a chip layout provided in this embodiment is implemented through the computer program.

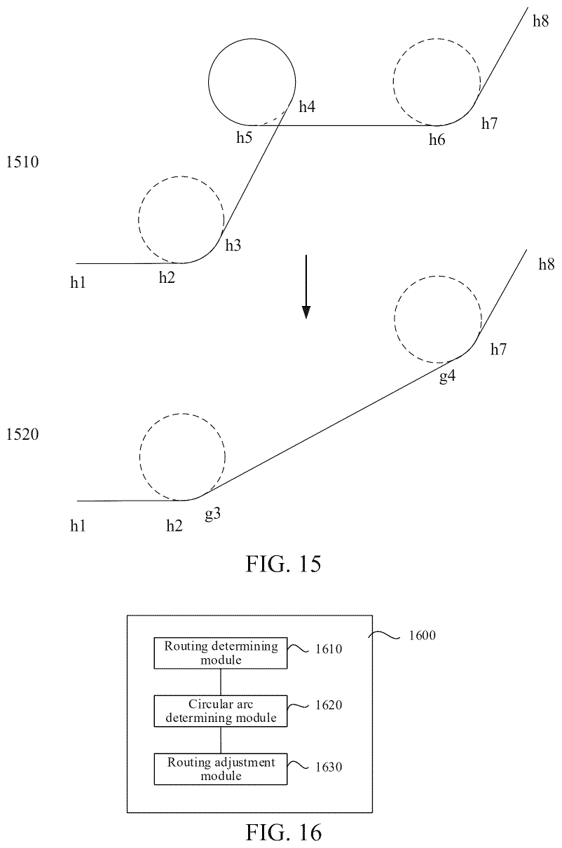

As shown in 1400 in FIG. 14, an algorithm for automatically recognizing and properly avoiding signal lines winding around is designed in this application, a problem of the signal lines winding around during arrangement is successively resolved, so that the arrangement of the signal lines is more proper and highly efficient. An initial path point is first arranged, and a circular arc is determined by traversing routing edge endpoints. Routing edge is a triangulated line on which the initial path point is located, and the routing edge endpoint is a triangulation point. In some embodiments, the triangulation point is a vertex of a component. There are a plurality of path points in a round of traverse, so that there are a plurality of endpoints of triangulated lines. A point that needs to be bypassed needs to be selected from the endpoints as a center of a circle by sorting, and a radius needs to be determined. A process of traverse refers to the foregoing embodiment, and recursive traverse is mainly performed. At the beginning, only two points, a start point and an end point, and one line are needed, and are divided into two in each round subsequently, to select a proper point in a current round, until no proper point is found, and the recursion stops. After all endpoints that need to be bypassed are determined, all circular arcs and radiuses are determined according to a radius of a circle corresponding to each endpoint. All the circular arcs are traversed, and winding-around recognition is performed. Whether a first direction is the same as a second direction is determined. If the first direction is the same as the second direction, it is considered that a circular arc is not a target circular arc; and if the first direction is different from the second direction, it is considered that the circular arc is the target circular arc, and the circular arc is removed. Whether the traverse is completed is determined. When the traverse for all the circular arcs is completed, the routing ends. That is, a main implementation is to traverse each circular arc on a path line, and detect whether the circular arc winds around. If the circular arc winds around, the circular arc is deleted, and positions of points of tangency of preceding and subsequent circular arcs of the deleted circular arc are re-calculated for connection. Specifically, FIG. 15 is used as an example. In routing 1510 in FIG. 15, assuming that a routing direction is from a first routing port h1 to a second routing port h8, the routing includes a tangent segment h1h2, a circular arc h2 counterclockwise to h3, a tangent segment h3h4, a circular arc h4 counterclockwise to h5, a tangent segment h5h6, a circular arc h6 counterclockwise to h7, and a tangent segment h7h8. According to the technical solution provided in the foregoing embodiment, the circular arc h4 counterclockwise to h5 winds around and rotates reversely. Based on the technical solution provided in this embodiment of this application, the circular arc h4 counterclockwise to h5 is considered as the target circular arc, namely, the circular arc that needs to be deleted. After the circular arc is deleted, the tangent segment h3h4 and the tangent segment h5h6 are correspondingly deleted. As shown in 1520 in FIG. 15, a common tangent, namely, a tangent segment g3g4, between a circle on which the circular arc h2 counterclockwise to h3 is located and a circle on which the circular arc h6 counterclockwise to h7 is located is re-determined. According to the tangent segment g3g4, a renewed circular arc h2 counterclockwise to g3 and a renewed circular arc g4 counterclockwise to h7 that are connected to the tangent segment can be obtained. This process may be analogized to an operation of deleting a node in a singly linked list and connecting a preceding node to a following node of the node. The routing determined based on the technical solutions provided in the embodiments of this application completely resolve a problem of signal lines winding around during routing, and a signal line is not excessively close to or even overlap with an adjacent signal line.

A core link of an improved algorithm provided in this application is automatic recognition and avoiding for the signal line winding around. When corresponding analysis and recognition are performed on a circular arc, if arcwind is not the same as fcwind, arcwind being a path direction of a circular arc, namely, the second direction, and tfcwind being a direction from a start point of tangency of a circular arc to an end point of tangency to a center of a circular arc, namely, the first direction, the circular arc winds around, and avoiding needs to be performed subsequently. If arcwind is the same as tfcwind, there is no-winding around situation. Proper avoiding of signal lines winding around is implemented by deleting winding-around circular arcs and connecting preceding and subsequent circular arcs by re-calculating points of tangency. In some embodiments, because a position of a point of tangency of a circular arc dynamically changes, the following two cases may occur during arrangement. 1. A circular arc is normal and does not wind around at the beginning. However, a position of a point of tangency changes, so that the circular arc winds around. 2. A circular arc winds around at the beginning. However, an adjacent circular arc changes, and a position of a point of tangency correspondingly changes. Therefore, the circular arc is restored to a normal state. Based on the foregoing analysis, recognition and determining logic for the winding-around circular arcs in the algorithm is set after positions of points of tangency of circular arcs are completely determined (through recursive traverse for the initial path point and finding the most proper triangulation point as the middle point to perform bisection recursion, all centers and radiuses of circles that need to be bypassed are determined, and corresponding tangent points are determined), to perform corresponding determining and avoiding. In addition, after the winding-around circular arcs are deleted, positions of points of tangency of the preceding and subsequent circular arcs of the deleted circular arcs (if exist) need to be re-calculated, so that the signal lines transition between the circular arcs more smoothly and properly.

In an exemplary embodiment, a chip is further provided. The chip is obtained by manufacturing based on a chip layout. Routing on the chip layout is obtained through the method for routing on a chip layout in the foregoing embodiments. In some embodiments, the chip is a quantum chip.

The following is an apparatus embodiment of this application, and may be used for performing method embodiments of this application. For details not disclosed in the apparatus embodiment of this application, refer to the method embodiments of this application.

FIG. 16 is a block diagram of an apparatus for routing on a chip layout according to an embodiment of this application. The apparatus has a function of implementing the foregoing method examples, and the function may be implemented through hardware, or may be implemented in such a manner that the hardware executes related software. The apparatus may be the computer device described above, or may be disposed in the computer device. As shown in FIG. 16, an apparatus 1600 includes: a routing determining module 1610, a circular arc determining module 1620, and a routing adjustment module 1630.

The routing determining module 1610 is configured to determine routing from a first routing port to a second routing port on the chip layout. The routing includes tangent segments and circular arcs that are alternately connected. Each circular arc uses a vertex on the chip layout as a center, and bypasses a component corresponding to the vertex. The vertex is a point corresponding to a component on a path between the first routing port and the second routing port.

The circular arc determining module 1620 is configured to perform recognition on the circular arcs included in the routing, to determine a target circular arc. The target circular arc is a circular arc in a winding-around state. The winding-around state means that a central angle corresponding to the circular arc is greater than a threshold.

The routing adjustment module 1630 is configured to remove the target circular arc, and adjust the routing, to obtain adjusted routing.

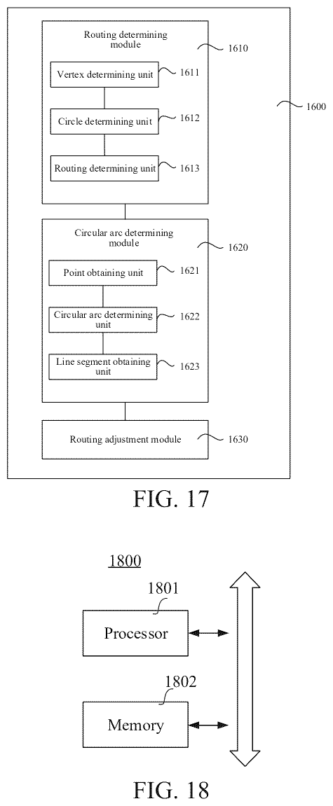

In some embodiments, as shown in FIG. 17, the circular arc determining module 1620 includes a point obtaining unit 1621 and a circular arc determining unit 1622.

The point obtaining unit 1621 is configured to obtain, for each circular arc, a start point of tangency of the circular arc connected to a first tangent segment, a vertex corresponding to the circular arc, and an end point of tangency of the circular arc connected to a second tangent segment. In a routing direction from the first routing port to the second routing port, the routing passes by the first tangent segment, the circular arc, and the second tangent segment in sequence.

The circular determining unit 1622 is configured to determine whether the circular arc is the target circular arc according to a positional relationship between the vertex corresponding to the circular arc and the end point of tangency.

In some embodiments, the circular arc determining unit 1622 is configured to determine a first direction and a second direction. The first direction is a rotation direction from the start point of tangency to the end point of tangency to the vertex corresponding to the circular arc, and the second direction is a rotation direction from the start point of tangency along the circular arc to the end point of tangency. Each of the rotation directions is clockwise or counterclockwise. If the first direction is different from the second direction, it is determined that the circular arc is the target circular arc; or if the first direction is the same as the second direction, it is determined that the circular arc is not the target circular arc.

In some embodiments, the circular arc determining unit 1622 is further configured to determine a central angle corresponding to the circular arc. The central angle uses the vertex corresponding to the circular arc as a vertex, one edge of the central angle passes by the start point of tangency, and the other edge of the central angle passes by the end point of tangency. If the central angle is greater than the threshold, it is determined that the circular arc is the target circular arc; or if the central angle is less than or equal to the threshold, it is determined that the circular arc is not the target circular arc.

In some embodiments, as shown in FIG. 17, the circular arc determining module 1620 further includes a line segment obtaining unit 1623.

The line segment obtaining unit 1623 is configured to obtain, for each circular arc, a first tangent segment and a second tangent segment connected to the circular arc. In a routing direction from the first routing port to the second routing port, the routing passes by the first tangent segment, the circular arc, and the second tangent segment in sequence.

The circular determining unit 1622 is configured to determine whether the circular arc is the target circular arc according to a positional relationship between the first tangent segment and the second tangent segment.

In some embodiments, the circular determining unit 1622 is further configured to determine, if the first tangent segment intersects with the second tangent segment, that the circular arc is the target circular arc; or determine, if the first tangent segment does not intersect with the second tangent segment, that the circular arc is not the target circular arc.

In some embodiments, the routing adjustment module 1630 is configured to remove the target circular arc, and generate a tangent segment connecting a preceding connecting object to a subsequent connecting object of the target circular arc, to obtain the adjusted routing. The preceding connecting object is a preceding circular arc or the first routing port, and the subsequent connecting object is a subsequent circular arc or the second routing port.

In some embodiments, the circular arc determining module 1620 is further configured to perform recognition on the circular arc included in the routing respectively, to determine a target circular arc; and end a procedure if the routing does not include the target circular arc, to obtain an adjusted chip layout.

In some embodiments, as shown in FIG. 17, the routing determining module 1610 includes a vertex determining unit 1611, a circle determining unit 1612, and a routing determining unit 1613.

The vertex determining unit 1611 is configured to determine at least one vertex from points corresponding to components on the chip layout.

The circle determining unit 1612 is configured to determine, for a k^{th} vertex of the at least one vertex, a circle using the k^{th} vertex as a center, k being a positive integer.

The routing determining unit 1613 is configured to determine initial routing according to the first routing port, the second routing port, and circles respectively corresponding to the at least one vertex.

In some embodiments, the routing determining unit 1613 is configured to determine a tangent through the first routing port to a circle corresponding to a first vertex, and determine a point of tangency as a start point of tangency corresponding to the first vertex; make a common tangent between the circle corresponding to the k^{th} vertex and a circle corresponding to a (k+1)^{th} vertex, determine an intersection point between the common tangent and the circle corresponding to the k^{th} vertex as an end point of tangency corresponding to the k^{th} vertex, and determine an intersection point between the common tangent and the circle corresponding to the (k+1)^{th} vertex as a start point of tangency corresponding to the (k+1)^{th} vertex; determine a tangent through the second routing port to a circle corresponding to a last vertex, and determine a point of tangency as an end point of tangency corresponding to the last vertex; determine a circular arc formed by the start point of tangency and the end of tangency corresponding to the k^{th} vertex as the circular arc corresponding to the k^{th} vertex; and alternately connect tangent segments and circular arcs corresponding to the at least one vertex in sequence starting from the first routing port until the second routing port is connected, to obtain the initial routing.

In some embodiments, the circle determining unit 1612 is configured to determine a radius corresponding to the circle corresponding to the k^{th} vertex according to a quantity of lines that are arranged at the k^{th} vertex, when the quantity of lines that are arranged is 0, the radius of the circle corresponding to the k^{th} vertex being equal to a shortest safety distance; and when the quantity of lines that are arranged is s, the radius of the circle corresponding to the k^{th} vertex being equal to a sum of the shortest safety distance and a product of s and a routing spacing, s being a positive integer, and the shortest safety distance and the routing spacing being constants; and determine the circle using the k^{th} vertex as the center according to the radius of the circle corresponding to the k^{th} vertex.

In some embodiments, the vertex determining unit 1611 is configured to determine a vertex corresponding to an initial line segment according to distances from points of the components to the initial line segment, the initial line segment being a line segment formed by a connection line between the first routing port and the second routing port; use the vertex as a middle point, determine a first line segment according to connection line between the middle point and a start point of the initial line segment, and determine a second line segment according to a connection line between the middle point and an end point of the initial line segment; and use the first line segment and the second line segment as the initial line segment separately, perform the determining a vertex corresponding to an initial line segment until a line segment formed by any two adjacent points corresponding to no vertex, and end a procedure, any one of adjacent points including at least one of the following: the first routing port, at least one vertex that is determined, or the second routing port.

When an apparatus provided in the foregoing embodiment implements functions, division of the foregoing functional modules is merely used as an example for description. In practice, the foregoing functions may be assigned to and completed by different functional modules as required. That is, a content structure of the device may be divided into different functional modules to complete all or some of the functions described above. In addition, the apparatus provided in the foregoing embodiment belongs to the same conception as the method embodiments. For a specific implementation process thereof, reference may be made to the method embodiments. Details are not described herein again.

FIG. 18 is a structural block diagram of a computer device 1800 according to an embodiment of this application. The computer device 1800 may be any electronic device having data computing, processing, and storage capabilities. The computer device 1800 may be configured to implement the routing method for routing on a chip layout provided in the foregoing embodiments.

Generally, the computer device 1800 includes: a processor 1801 and a memory 1802.

The processor 1801 may include one or more processing cores, such as a 4-core processor and an 8-core processor. The processor 1801 may be implemented in at least one hardware form of a digital signal processor (DSP), a field-programmable gate array (FPGA), and a programmable logic array (PLA). The processor 1801 may alternatively include a main processor and a coprocessor. The main processor is a processor configured to process data in an active state, also referred to as a central processing unit (CPU). The coprocessor is a low-power consumption processor configured to process data in a standby state. In some embodiments, the processor 1801 may be integrated with a graphics processing unit (GPU). The GPU is configured to render and draw content that needs to be displayed on a display screen. In some embodiments, the processor 1801 may further include an artificial intelligence (AI) processor. The AI processor is configured to process computing operations related to machine learning.

The memory 1802 may include one or more computer-readable storage media. The computer-readable storage medium may be non-transient. The memory 1802 may further include a high-speed random access memory and a nonvolatile memory, for example, one or more disk storage devices or flash storage devices. In some embodiments, the non-transient computer-readable storage medium in the memory 1802 is configured to store a computer program. The computer program is configured to be executed by one or more processors to implement the foregoing method for routing on a chip layout.

A person skilled in the art may understand that the structure shown in FIG. 18 does not constitute any limitation on the computer device 1800, and the computer device 1800 may include more or fewer components than those shown in the figure, or some components may be combined, or a different component deployment may be used.

In an exemplary embodiment, a non-transitory computer-readable storage medium is further provided. The computer-readable storage medium has a computer program stored therein. The computer program is executed by a processor to implement the foregoing method for routing on a chip layout. In some embodiments, the computer-readable storage medium may include: a read-only memory (ROM), a random access memory (RAM), a solid state drive (SSD), an optical disc, and the like. The random access memory may include a resistance random access memory (ReRAM) and a dynamic random access memory (DRAM).

In an exemplary embodiment, a computer program product is further provided. The computer program product includes a computer program. The computer program is stored in a computer-readable storage medium. A processor of a computer device reads the computer program from the computer-readable storage medium. The processor executes the computer program, to cause the computer device to perform the foregoing method for routing on a chip layout.

“Plurality of” mentioned in the specification means two or more. “And/or” describes an association relationship between associated objects and indicates that there may be three relationships. For example, A and/or B may indicate three cases that only A exists, both A and B exist, and only B exists. The character “/” generally indicates an “or” relationship between the associated objects. In addition, the operation numbers described in this specification merely schematically show a possible performing sequence of the operations. In some other embodiments, the operations may not be performed according to the number sequence. For example, two operations with different numbers may be performed simultaneously, or two operations with different numbers may be performed according to a sequence contrary to the sequence shown in the figure. This is not limited in the embodiments of this application.

The foregoing descriptions are merely exemplary embodiments of this application, but are not intended to limit this application. Any modification, equivalent replacement, or improvement made within the spirit and principle of this application shall fall within the protection scope of this application.

What is claimed is:

1. A method for designing routing on a chip layout performed by a computer device, the method comprising:
obtaining routing from a first routing port to a second routing port on the chip layout, the routing comprising tangent segments and circular arcs, each circular arc having a first endpoint and a second endpoint with the first endpoint being the same as an endpoint of a corresponding tangent segment connected to the circular arc;
identifying, among the circular arcs comprised in the routing, a target circular arc in a winding-around state, in which a central angle corresponding to the target circular arc from its first endpoint to its second endpoint is greater than a threshold; and
removing the target circular arc from the routing to obtain an updated routing that no winding-around state between a pair of adjacent tangent segment and circular arc.

2. The method according to claim 1, wherein the identifying, among the circular arcs comprised in the routing, a target circular arc in a winding-around state comprises:
obtaining, for each circular arc, a start point of tangency of the circular arc connected to a first tangent segment as a first endpoint of the circular arc, a vertex corresponding to the circular arc, and an end point of tangency of the circular arc connected to a second tangent segment as a second endpoint of the circular arc, the routing passing by the first tangent segment, the circular arc, and the second tangent segment in sequence in a routing direction from the first routing port to the second routing port; and
determining whether the circular arc is the target circular arc according to a positional relationship among the start point of tangency, the vertex corresponding to the circular arc, and the end point of tangency.

3. The method according to claim 2, wherein the determining whether the circular arc is the target circular arc according to a positional relationship among the start point of tangency, the vertex corresponding to the circular arc, and the end point of tangency comprises:
determining a first direction and a second direction, the first direction being a rotation direction from the start point of tangency to the end point of tangency relative to the vertex corresponding to the circular arc, and the second direction being a rotation direction from the start point of tangency along the circular arc relative to the end point of tangency; and
determining that the circular arc is the target circular arc when the first direction is different from the second direction.

4. The method according to claim 2, wherein the determining whether the circular arc is the target circular arc according to a positional relationship among the start point of tangency, the vertex corresponding to the circular arc, and the end point of tangency comprises:
determining a central angle corresponding to the circular arc using the vertex corresponding to the circular arc as a vertex, one edge of the central angle passing by the start point of tangency, and the other edge of the central angle passing by the end point of tangency; and
determining that the circular arc is the target circular arc when the central angle is greater than the threshold.

5. The method according to claim 1, wherein the identifying, among the circular arcs comprised in the routing, a target circular arc in a winding-around state comprises:
obtaining, for each circular arc, a first tangent segment and a second tangent that are connected to the circular arc, the routing passing by the first tangent segment, the circular arc, and the second tangent segment in sequence in a routing direction from the first routing port to the second routing port; and
determining whether the circular arc is the target circular arc according to a positional relationship between the first tangent segment and the second tangent segment.

6. The method according to claim 5, wherein the determining whether the circular arc is the target circular arc according to a positional relationship between the first tangent segment and the second tangent segment comprises:
determining that the circular arc is the target circular arc when the first tangent segment intersects with the second tangent segment.

7. The method according to claim 1, wherein the removing the target circular arc from the routing to obtain an updated routing that no winding-around state between a pair of adjacent tangent segment and circular arc comprises:
generating a tangent segment connecting a preceding connecting object to a subsequent connecting object of the target circular arc, the preceding connecting object being a preceding circular arc or the first routing port, and the subsequent connecting object being a subsequent circular arc or the second routing port.

8. The method according to claim 1, wherein the obtaining routing from a first routing port to a second routing port on the chip layout comprises:
determining at least one vertex from points corresponding to components on the chip layout;
determining, for a k^{th} vertex of the at least one vertex, a circle using the k^{th} vertex as a center, k being a positive integer; and
determining initial routing according to the first routing port, the second routing port, and circles respectively corresponding to the at least one vertex.

9. A computer device comprising a processor and a memory, the memory having a computer program stored therein that, when executed by the processor, causes the computer device to implement a method for designing routing on a chip layout including:
obtaining routing from a first routing port to a second routing port on the chip layout, the routing comprising tangent segments and circular arcs, each circular arc having a first endpoint and a second endpoint with the first endpoint being the same as an endpoint of a corresponding tangent segment connected to the circular arc;
identifying, among the circular arcs comprised in the routing, a target circular arc in a winding-around state, in which a central angle corresponding to the target circular arc from its first endpoint to its second endpoint is greater than a threshold; and
removing the target circular arc from the routing to obtain an updated routing that no winding-around state between a pair of adjacent tangent segment and circular arc.

10. The computer device according to claim 9, wherein the identifying, among the circular arcs comprised in the routing, a target circular arc in a winding-around state comprises:
obtaining, for each circular arc, a start point of tangency of the circular arc connected to a first tangent segment as a first endpoint of the circular arc, a vertex corresponding to the circular arc, and an end point of tangency of the circular arc connected to a second tangent segment as a second endpoint of the circular arc, the routing passing by the first tangent segment, the circular arc, and the second tangent segment in sequence in a routing direction from the first routing port to the second routing port; and
determining whether the circular arc is the target circular arc according to a positional relationship among the start point of tangency, the vertex corresponding to the circular arc, and the end point of tangency.

11. The computer device according to claim 10, wherein the determining whether the circular arc is the target circular arc according to a positional relationship among the start point of tangency, the vertex corresponding to the circular arc, and the end point of tangency comprises:
determining a first direction and a second direction, the first direction being a rotation direction from the start point of tangency to the end point of tangency relative to the vertex corresponding to the circular arc, and the second direction being a rotation direction from the start point of tangency along the circular arc relative to the end point of tangency; and
determining that the circular arc is the target circular arc when the first direction is different from the second direction.

12. The computer device according to claim 10, wherein the determining whether the circular arc is the target circular arc according to a positional relationship among the start point of tangency, the vertex corresponding to the circular arc, and the end point of tangency comprises:
determining a central angle corresponding to the circular arc using the vertex corresponding to the circular arc as a vertex, one edge of the central angle passing by the start point of tangency, and the other edge of the central angle passing by the end point of tangency; and
determining that the circular arc is the target circular arc when the central angle is greater than the threshold.

13. The computer device according to claim 9, wherein the identifying, among the circular arcs comprised in the routing, a target circular arc in a winding-around state comprises:
obtaining, for each circular arc, a first tangent segment and a second tangent that are connected to the circular arc, the routing passing by the first tangent segment, the circular arc, and the second tangent segment in sequence in a routing direction from the first routing port to the second routing port; and
determining whether the circular arc is the target circular arc according to a positional relationship between the first tangent segment and the second tangent segment.

14. The computer device according to claim 13, wherein the determining whether the circular arc is the target circular arc according to a positional relationship between the first tangent segment and the second tangent segment comprises:
determining that the circular arc is the target circular arc when the first tangent segment intersects with the second tangent segment.

15. The computer device according to claim 9, wherein the removing the target circular arc from the routing to obtain an updated routing that no winding-around state between a pair of adjacent tangent segment and circular arc comprises:
generating a tangent segment connecting a preceding connecting object to a subsequent connecting object of the target circular arc, the preceding connecting object being a preceding circular arc or the first routing port, and the subsequent connecting object being a subsequent circular arc or the second routing port.

16. The computer device according to claim 9, wherein the obtaining routing from a first routing port to a second routing port on the chip layout comprises:
determining at least one vertex from points corresponding to components on the chip layout;
determining, for a k^{th} vertex of the at least one vertex, a circle using the k^{th} vertex as a center, k being a positive integer; and
determining initial routing according to the first routing port, the second routing port, and circles respectively corresponding to the at least one vertex.

17. A non-transitory computer-readable storage medium, the computer-readable storage medium having a computer program stored therein that, when loaded and executed by a processor of a computer device, causes the computer device to implement a method for designing routing on a chip layout including:
obtaining routing from a first routing port to a second routing port on the chip layout, the routing comprising tangent segments and circular arcs, each circular arc having a first endpoint and a second endpoint with the first endpoint being the same as an endpoint of a corresponding tangent segment connected to the circular arc;
identifying, among the circular arcs comprised in the routing, a target circular arc in a winding-around state, in which a central angle corresponding to the target circular arc from its first endpoint to its second endpoint is greater than a threshold; and
removing the target circular arc from the routing to obtain an updated routing that no winding-around state between a pair of adjacent tangent segment and circular arc.

18. The non-transitory computer-readable storage medium according to claim 17, wherein the identifying, among the circular arcs comprised in the routing, a target circular arc in a winding-around state comprises:
obtaining, for each circular arc, a start point of tangency of the circular arc connected to a first tangent segment as a first endpoint of the circular arc, a vertex corresponding to the circular arc, and an end point of tangency of the circular arc connected to a second tangent segment as a second endpoint of the circular arc, the routing passing by the first tangent segment, the circular arc, and the second tangent segment in sequence in a routing direction from the first routing port to the second routing port; and
determining whether the circular arc is the target circular arc according to a positional relationship among the start point of tangency, the vertex corresponding to the circular arc, and the end point of tangency.

19. The non-transitory computer-readable storage medium according to claim 17, wherein the identifying, among the circular arcs comprised in the routing, a target circular arc in a winding-around state comprises:
obtaining, for each circular arc, a first tangent segment and a second tangent that are connected to the circular arc, the routing passing by the first tangent segment, the circular arc, and the second tangent segment in sequence in a routing direction from the first routing port to the second routing port; and
determining whether the circular arc is the target circular arc according to a positional relationship between the first tangent segment and the second tangent segment.

20. The non-transitory computer-readable storage medium according to claim 17, wherein the removing the target circular arc from the routing to obtain an updated routing that no winding-around state between a pair of adjacent tangent segment and circular arc comprises:
generating a tangent segment connecting a preceding connecting object to a subsequent connecting object of the target circular arc, the preceding connecting object being a preceding circular arc or the first routing port, and the subsequent connecting object being a subsequent circular arc or the second routing port.
